(19) United States
(12) Patent Application Publication
(10) Pub. No.: US 2016/0013101 A1
(43) Pub. Date: Jan. 14, 2016

(54) PRE-TREATMENT METHOD OF PLATING, PLATING SYSTEM, AND RECORDING MEDIUM

(71) Applicant: Tokyo Electron Limited, Tokyo (JP)

(72) Inventors: Yuichiro Inatomi, Nirasaki City (JP); Takashi Tanaka, Nirasaki City (JP)

(21) Appl. No.: 14/790,119

(22) Filed: Jul. 2, 2015

(30) Foreign Application Priority Data
Jul. 9, 2014 (JP) 2014-141695

(51) Int. Cl. H01L 21/768; B01J 37/02; B01J 37/08; B01J 23/44; B01J 35/00; C23C 18/16; B01J 21/06

(52) U.S. Cl. CPC H01L 21/76874; C23C 18/1632; C23C 18/1628; H01L 21/76864; B01J 37/0244; B01J 21/06; B01J 23/44; B01J 35/0006; B01J 37/08

(57) ABSTRACT

A pre-treatment method of plating can suppress a catalyst layer from being peeled off from a substrate. The pre-treatment method of forming the catalyst layer on the substrate includes forming the catalyst layer 22 by adsorbing a catalyst 22a on the substrate 2; and forming a catalyst fixing layer 27 on the catalyst layer 22.

### CROSS-REFERENCE TO RELATED APPLICATION

This application claims the benefit of Japanese Patent Application No. 2014-141695 filed on Jul. 9, 2014, the entire disclosures of which are incorporated herein by reference.

### TECHNICAL FIELD

The embodiments described herein pertain generally to a pre-treatment method of plating and a plating system of forming a catalyst layer on a substrate, and a recording medium therefor.

### BACKGROUND

Recently, semiconductor devices such as a LSI or the like have been required to have higher density in order to meet requirements for reducing the mounting space or for improving the processing rate. As an example of a technology that achieves the high density, there has been known a multilayer wiring technology of manufacturing a multilayer substrate, such as a three-dimensional LSI or the like, by stacking multiple wiring substrates.

According to the multilayer wiring technology, a through-via-hole, which penetrates the wiring substrates and in which a conductive material such as copper (Cu) is buried, is typically formed in the wiring substrate in order to obtain electrical connection between the wiring substrates. As an example of a technology for forming the through-via-hole in which a conductive material is buried, there has been known an electroless plating method.

As a specific method of producing a wiring substrate, there is known a method in which a substrate having a recess is prepared, a barrier film as a Cu diffusion barrier film is formed on the recess of the substrate, and a seed film is formed on the barrier film by electroless Cu plating.

Thereafter, Cu is buried within the recess by electrolytic Cu plating, and the substrate in which the Cu is buried is then thinned by a polishing method such as chemical mechanical polishing. Through this processing, a wiring substrate having a through-via-hole in which the Cu is buried is manufactured.

To form the barrier film of the aforementioned wiring substrate, by adsorbing a catalyst onto the substrate in advance, a catalyst layer is formed, and by performing a plating processing on the catalyst layer, a barrier film is obtained. The barrier film is then baked, so that moisture within the barrier film is removed and the bond between metals is strengthened.

Meanwhile, there has been developed a technique using a palladium nanoparticle or the like as a catalyst in the case of adsorbing the catalyst onto the substrate.

Patent Document 1: Japanese Patent Laid-open Publication No. 2013-067856

As described above, there has been developed a technique using a palladium nanoparticle or the like as a catalyst in the case of adsorbing the catalyst to a substrate, and in this case, an adhesion layer may be previously formed on the substrate in order to adsorb the catalyst.

However, even if the adhesion layer is formed on the substrate, when a thickness of a plating layer is increased, the palladium nanoparticle may be peeled off from the adhesion layer. In this case, it is difficult to form the plating layer with high accuracy.

### SUMMARY

In view of the foregoing, an exemplary embodiment provides a pre-treatment method of plating and a plating system, which can form a catalyst layer to suppress a catalyst from being peeled off from a substrate, as a pre-treatment of performing a plating processing on the substrate, and a recording medium therefor.

In one exemplary embodiment, a pre-treatment method of plating includes preparing a substrate; forming a catalyst layer by adsorbing a catalyst on the substrate; and forming a catalyst fixing layer, which is configured to fix the catalyst to the substrate, on the catalyst layer.

In another exemplary embodiment, a plating system includes a catalyst layer forming unit configured to form a catalyst layer by adsorbing a catalyst on a substrate; a catalyst fixing layer forming unit configured to form a catalyst fixing layer, which is configured to fix the catalyst to the substrate, on the catalyst layer; and a substrate transfer unit configured to transfer the substrate between the catalyst layer forming unit and the catalyst fixing layer forming unit.

In yet another exemplary embodiment, a computer-readable recording medium has stored thereon computer-executable instructions that, in response to execution, cause a plating system to perform a pre-treatment method of plating. Here, the pre-treatment method includes preparing a substrate; forming a catalyst layer by adsorbing a catalyst on the substrate; and forming a catalyst fixing layer, which is configured to fix the catalyst to the substrate, on the catalyst layer.

According to the exemplary embodiments, since the catalyst fixing layer configured to fix the catalyst formed on the substrate is provided, the catalyst is not peeled off from the substrate. For this reason, a plating layer to be formed by a post-processing is not peeled off from the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a block diagram illustrating a plating system according to an exemplary embodiment;

FIG. 2 is a flowchart showing a plating method including a pre-treatment method of plating according to the exemplary embodiment;

FIG. 3A to FIG. 3G are diagrams illustrating a substrate to which a plating method is performed;

FIG. 4A and FIG. 4B are side cross-sectional views illustrating a catalyst layer and a catalyst fixing layer formed on the substrate according to the exemplary embodiment;

FIG. 5A and FIG. 5B are side cross-sectional views illustrating a catalyst layer formed on a substrate according to a comparative example;

FIG. 6A and FIG. 6B are side cross-sectional views illustrating the catalyst layer, the catalyst fixing layer, and a plating layer formed on the substrate according to the exemplary embodiment;

FIG. 7A and FIG. 7B are side cross-sectional views illustrating the catalyst layer and a plating layer formed on the substrate according to the comparative example;

FIG. 8 is a side cross-sectional view illustrating a catalyst layer forming unit;

FIG. 9 is a plan view illustrating the catalyst layer forming unit; and

FIG. 10 is a diagram illustrating a heating unit.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

### Plating System

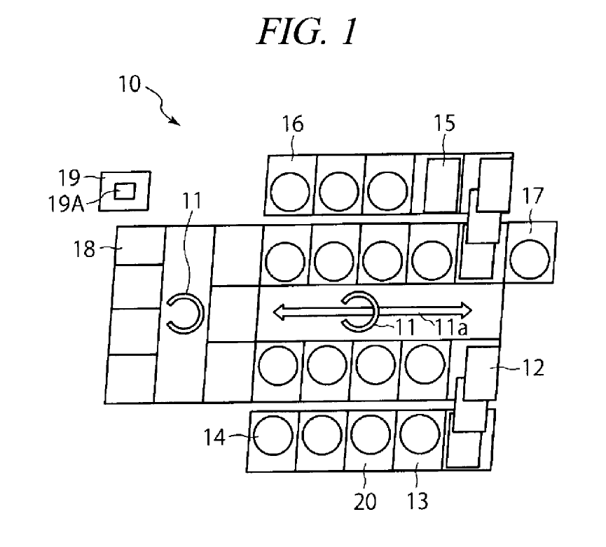

An exemplary embodiment will be described with reference to FIG. 1 to FIG. 10.

An overall configuration of a plating system will be described with reference to FIG. 1.

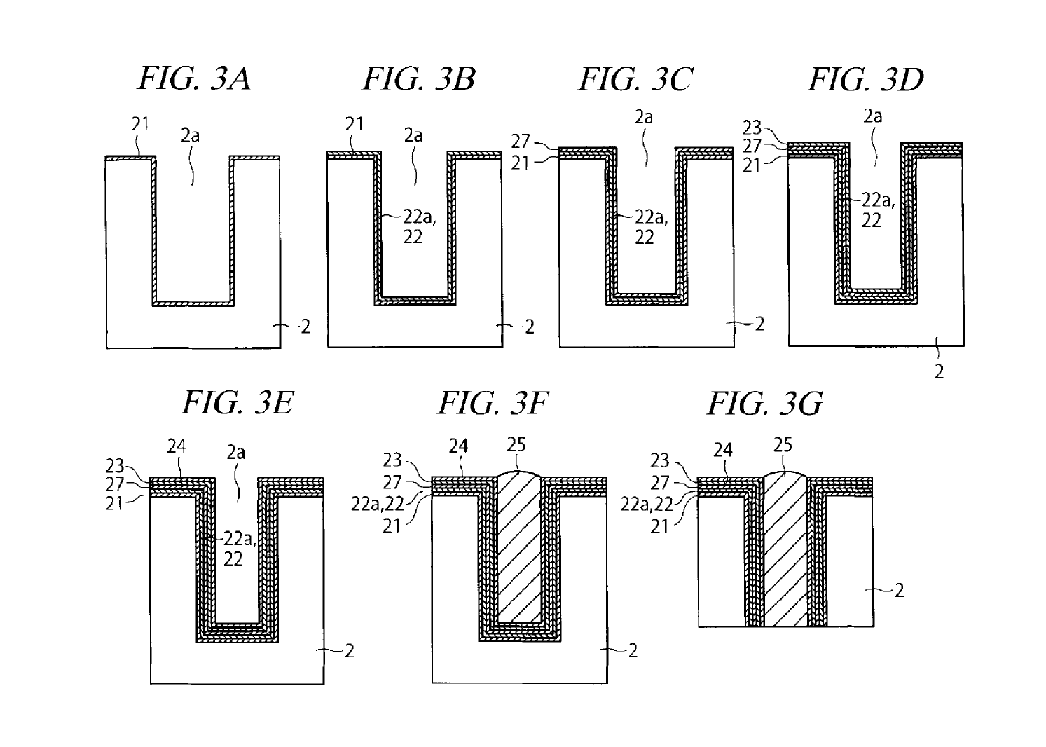

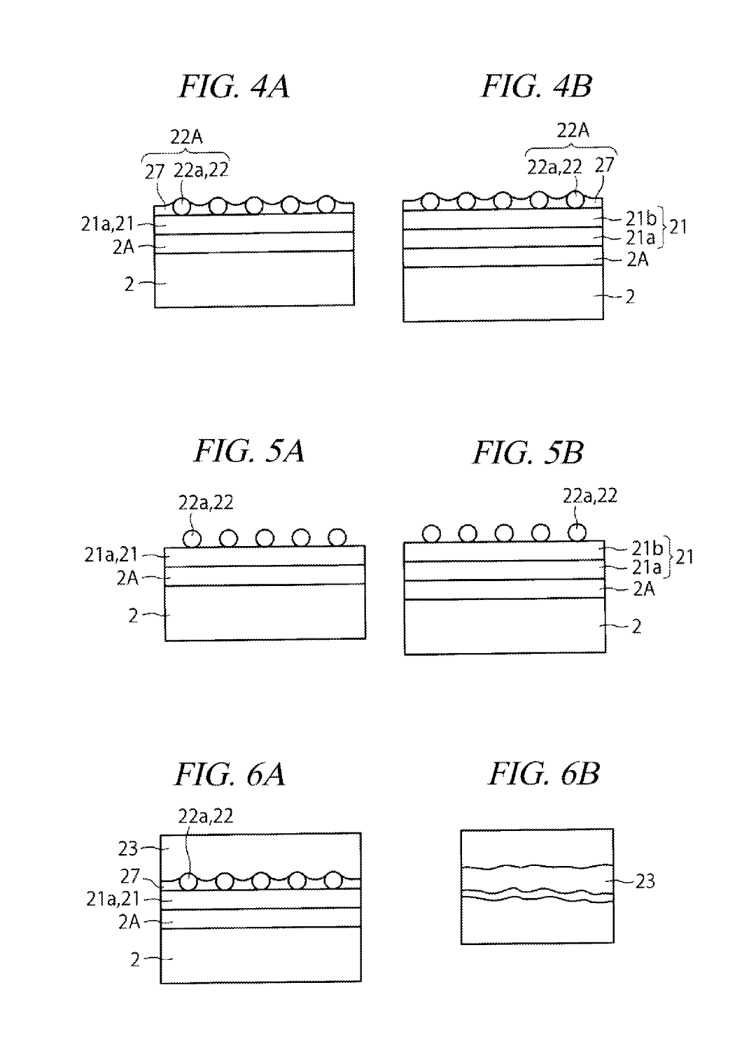

As illustrated in FIG. 1, a plating system 10 is configured to perform a plating processing to a substrate (silicon substrate) 2, such as a semiconductor wafer, having a recess 2a (see FIG. 3A to FIG. 3G). In this case, a TEOS processing is previously performed to the silicon substrate 2, so that a TEOS layer 2A is already formed thereon (see FIG. 4A and FIG. 4B).

The plating system 10 includes a cassette station 18 configured to place a cassette (not shown) which accommodates the substrate 2; a substrate transfer arm 11 configured to take out the substrate 2 from the cassette on the cassette station 18 and transfer the substrate 2; and a moving path 11a along which the substrate transfer arm 11 is moved.

Arranged at one side of the moving path 11a are an adhesion layer forming unit 12 configured to form an adhesion layer 21 to be described later by adsorbing a coupling agent such as a silane coupling agent onto the substrate 2; a catalyst layer forming unit 13 configured to form a catalyst layer 22 to be described later by adsorbing a catalyst 22a onto the adhesion layer 21 of the substrate 2; and a plating layer forming unit 14 configured to form a plating layer 23 serving as a Cu diffusion barrier film (barrier film) to be described later on the catalyst layer 22 of the substrate 2. Further, a catalyst fixing layer forming unit 20 configured to form a catalyst fixing layer 27 on the catalyst layer 22 and fix the catalyst layer 22 on the TEOS layer 2A of the substrate 2 with the catalyst fixing layer 27 is arranged to be adjacent to the catalyst layer forming unit 13.

Further, arranged at the other side of the moving path 11a are a heating unit 15 configured to bake the catalyst layer 22, the catalyst fixing layer 27 and the plating layer 23 formed on the substrate 2; and an electroless Cu plating layer forming unit 16 configured to form an electroless copper (Cu) plating layer 24, serving as a seed film to be described later, on the plating layer 23 formed on the substrate 2.

Further, an electrolytic Cu plating layer forming unit 17 configured to fill the recess 2a of the substrate 2 with an electrolytic copper (Cu) plating layer 25 while using the electroless Cu plating layer 24 as a seed film is provided adjacent to the heating unit 15.

The heating unit 15 functions as a first heating unit configured to bake the catalyst fixing layer 27 as described above and also functions as a second heating unit configured to bake the catalyst layer 22. Further, by heating the substrate 2 on which the plating layer 23 is formed with the heating unit 15, the plating layer 23 can be baked.

Furthermore, the catalyst 22a of the catalyst layer 22 functions as a catalyst when the plating layer 23 is formed. The catalyst fixing layer 27 is configured to fix the catalyst layer 22 to the substrate 2.

Further, the respective constituent components of the above-described plating system, for example, the cassette station 18, the substrate transfer arm 11, the adhesion layer forming unit 12, the catalyst layer forming unit 13, the catalyst fixing layer forming unit 20, the plating layer forming unit 14, the heating unit 15, the electroless Cu plating layer forming unit 16 and the electrolytic Cu plating layer forming unit 17 are controlled by a control unit 19 according to various types of programs recorded in a recording medium 19A provided in the control unit 19, so that various processes are performed on the substrate 2. Here, the recording medium 19A stores thereon various kinds of setup data or various kinds of programs such as a plating method to be described later. The recording medium 19A may be implemented by a computer-readable memory such as a ROM or a RAM, or a disk-type recording medium such as a hard disk, a CD-ROM, a DVD-ROM or a flexible disk, as commonly known in the art.

Hereinafter, the catalyst layer forming unit 13 configured to form the catalyst layer 22 will be further described.

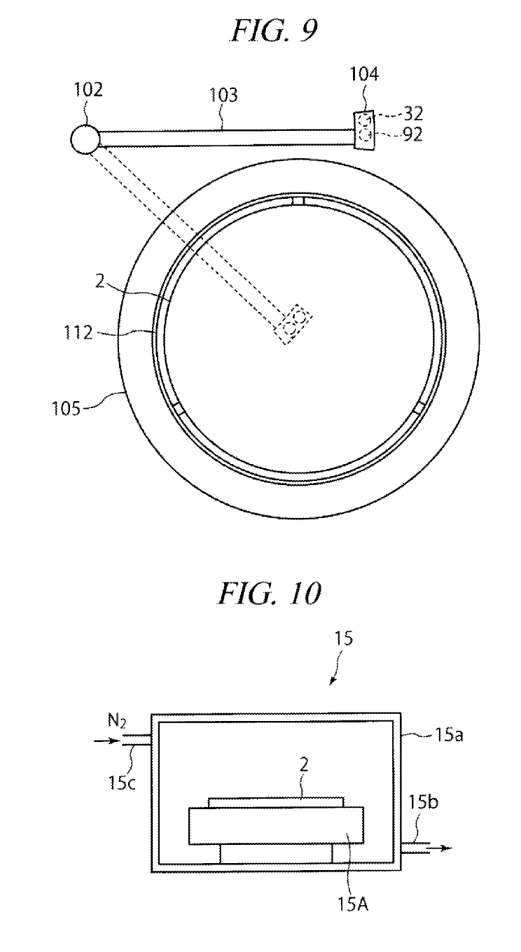

The catalyst layer forming unit 13 may be configured as a liquid processing apparatus illustrated in FIG. 8 and FIG. 9.

Further, the plating layer forming unit 14 and the electroless Cu plating layer forming unit 16 may also be configured as the same liquid processing apparatus as the catalyst layer forming unit 13. The catalyst layer forming unit 13 is the same as illustrated in FIG. 8 and FIG. 9.

That is, the catalyst layer forming unit 13 includes, as shown in FIG. 8 and FIG. 9, a substrate holding/rotating device (substrate accommodating unit) 110 configured to hold and rotate the substrate 2 within a casing 101; liquid supplying devices 30 and 90 configured to supply a catalyst liquid, a cleaning liquid or the like onto a surface of the substrate 2; a recovery cup 105 configured to receive and collect the catalyst liquid, the cleaning liquid or the like dispersed from the substrate 2; draining openings 124, 129 and 134 through which the catalyst liquid or the cleaning liquid collected by the recovery cup 105 is drained; liquid draining devices 120, 125 and 130 configured to drain the liquids collected through the draining openings; and a controller 160 configured to control the substrate holding/rotating device 110, the liquid supplying devices 30 and 90, the recovery cup 105 and the liquid draining devices 120, 125 and 130.

The substrate holding/rotating device 110 includes, as illustrated in FIG. 8 and FIG. 9, a hollow cylindrical rotation shaft 111 vertically extended within the casing 101; a turntable 112 provided on an upper end portion of the rotation shaft 111; a wafer chuck 113 disposed on a peripheral portion of a top surface of the turntable 112 to support the substrate 2; and a rotating device 162 configured to rotate the rotation shaft 111. The rotating device 162 is controlled by the controller 160, and the rotation shaft 111 is rotated by the rotating device 162. As a result, the substrate 2 supported on the wafer chuck 113 is rotated.

Now, the liquid supplying devices 30 and 90 configured to supply the catalyst liquid, a cleaning liquid, or the like onto the surface of the substrate 2 will be explained with reference to FIG. 8 and FIG. 9. The catalyst liquid supplying device 30 is a catalyst liquid supplying device configured to supply the catalyst liquid on the surface of the substrate 2. The cleaning liquid supplying device 90 is a cleaning liquid supplying device configured to supply a cleaning liquid onto the surface of the substrate 2.

As depicted in FIG. 8 and FIG. 9, a discharge nozzle 32 is provided at a nozzle head 104. The nozzle head 104 is provided at a tip end portion of an arm 103. The arm 103 is provided at a supporting shaft 102 rotated by a rotating device 165 to be moved in a vertical direction. A catalyst liquid supplying line of the catalyst liquid supplying device 30 is embedded within the arm 103. With this configuration, it is possible to discharge the catalyst liquid onto a target position on the surface of the substrate 2 through the discharge nozzle 32 from a required supply height.

The cleaning liquid supplying device 90 is configured to perform a cleaning processing on the substrate 2 as will be described later. As illustrated in FIG. 8, the cleaning liquid supplying device 90 includes a nozzle 92 provided at the nozzle head 104. In this configuration, either a cleaning liquid or a rinsing liquid is selectively discharged onto the surface of the substrate 2 from the nozzle 92.

Now, the liquid draining devices 120, 125 and 130 configured to drain out the catalyst liquid or the cleaning liquid dispersed from the substrate 2 will be elaborated with reference to FIG. 8. As shown in FIG. 8, the recovery cup 105, which can be moved up and down by an elevating device 164 and is provided with the draining openings 124, 129 and 134, is disposed within the casing 101. The liquid draining devices 120, 125 and 130 are configured to drain out the liquids collected through the draining openings 124, 129 and 134, respectively.

As depicted in FIG. 8, the plating liquid draining devices 120 and 125 include recovery flow paths 122 and 127 and waste flow paths 123 and 128, which are switched by flow path switching devices 121 and 126, respectively. Here, the catalyst liquid is collected and reused through the recovery flow paths 122 and 127, while the catalyst liquid is drained out through the waste flow paths 123 and 128. Further, as shown in FIG. 8, the processing liquid draining device 130 is only equipped with a waste flow path 133.

Further, as depicted in FIG. 8 and FIG. 9, the recovery flow path 122 of the catalyst liquid draining device 120 configured to drain the catalyst liquid is connected to an outlet side of the substrate accommodating unit 110, and a cooling buffer 120A configured to cool the catalyst liquid is provided at a portion of the recovery flow path 122 in the vicinity of the outlet side of the substrate accommodating unit 110.

Hereinafter, the catalyst fixing layer forming unit 20 will be described. The catalyst fixing layer forming unit 20 includes a spray-type coating device configured to discharge and coat a material for forming a catalyst fixing layer on the substrate 2, and is configured to form the catalyst fixing layer 27 on the catalyst layer 22 of the substrate 2.

Further, as the catalyst fixing layer forming unit 20, the liquid processing apparatus illustrated in FIG. 8 and FIG. 9 may be employed. In this case, the nozzle head 104 may be fixed above a central portion of the center of the substrate 2, and the material for forming the catalyst fixing layer may be supplied on the substrate 2 from the nozzle head 104 while rotating the substrate 2.

Otherwise, the catalyst fixing layer forming unit 20 may employ the liquid processing apparatus illustrated in FIG. 8 and FIG. 9 in which a slit-type nozzle is provided instead of the nozzle head 104. If the slit-type nozzle is used as such, the substrate 2 is not rotated but stopped within the liquid processing apparatus and the slit-type nozzle may be rotated above the substrate 2.

Now, the heating unit 15 will be elaborated.

The heating unit 15 includes, as illustrated in FIG. 10, an airtightly sealed casing 15a; and a hot plate 15A provided within the airtightly sealed casing 15a.

The airtightly sealed casing 15a of the heating unit 15 is provided with a transfer opening (not shown) through which the substrate 2 is transferred. An N₂ gas is supplied into the airtightly sealed casing 15a through an N₂ gas supply opening 15c.

Concurrently, the inside of the airtightly sealed casing 15a is evacuated through an exhaust port 15b, and by supplying the N₂ gas into the airtightly sealed casing 15a, the inside of the airtightly sealed casing 15a can be maintained under an inert gas atmosphere.

### Plating Method

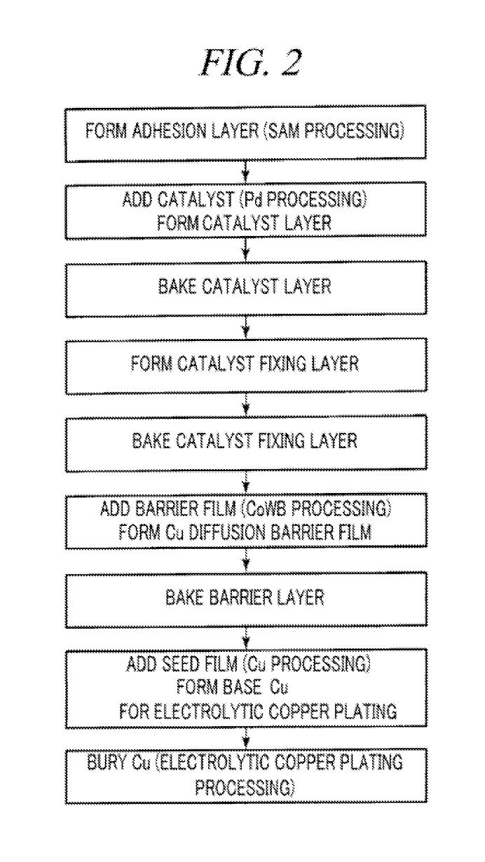

Hereinafter, an effect of the present exemplary embodiment as described above will be described with reference to FIG. 2 to FIG. 7B.

First, in a pre-processing, a recess 2a is formed on a substrate (silicon substrate) 2 such as a semiconductor wafer or the like, and then, a TEOS layer 2A is formed on the substrate 2. The substrate 2 having thereon the TEOS layer 2A is then transferred into the plating system 10 according to the example embodiment.

In the adhesion layer forming unit 12 of the plating system 10, an adhesion layer 21 is formed on the TEOS layer 2A of the substrate 2 having the recess 2a (FIG. 2 and FIG. 3A).

Here, as a method of forming the recess 2a on the substrate 2, a commonly known method in the art may be appropriately employed. Specifically, as a dry etching technique, for example, a general-purpose technique using a fluorine-based gas or a chlorine-based gas may be employed. Especially, in order to form a hole having a high aspect ratio (a hole depth/a hole diameter), a method using an ICP-RIE (Inductively Coupled Plasma Reactive Ion Etching) technique, which can perform a deep etching processing with a high speed, may be more appropriately adopted. Especially, a Bosch process in which an etching processing using sulfur hexafluoride (SF₆) and a protection processing using a teflon-based gas such as C₄F₈ are repeatedly performed may be appropriately utilized.

Further, the adhesion layer forming unit 12 has a decompression chamber (not shown) equipped with a heating unit. In the adhesion layer forming unit 12, a coupling agent such as a silane coupling agent is adsorbed onto the substrate 2 having the recess 2a, so that the adhesion layer 21 is formed on the TEOS layer 2A of the substrate 2 (SAM processing). The adhesion layer 21 formed by adsorbing the silane coupling agent is configured to improve adhesivity between the substrate 2 and a catalyst layer 22 to be described later, and includes a SAM layer 21a (see FIG. 4A).

Furthermore, as illustrated in FIG. 4B, a titanate-based adhesion layer (TPT layer) 21b is prepared by coating a titanate agent including a titanium oxide agent on the SAM layer 21a, and then, the adhesion layer 21 including the SAM layer 21a and the TPT layer 21b may be formed. Otherwise, the titanate-based adhesion layer (TPT layer) 21b is formed on the TEOS layer 2A of the substrate 2, and then, the adhesion layer 21 including the TPT layer 21b may be formed.

The substrate 2 on which the adhesion layer 21 is formed in the adhesion layer forming unit 12 is then transferred into the catalyst layer forming unit 13, which is configured as the liquid processing apparatus shown in FIG. 8 and FIG. 9, by the substrate transfer arm 11. In the catalyst layer forming unit 13, palladium nanoparticles serving as the catalyst 22a are adsorbed on the adhesion layer 21 of the substrate 2, so that the catalyst layer 22 is formed (FIG. 3B).

To be specific, in the catalyst layer forming unit 13 illustrated in FIG. 8 and FIG. 9, the catalyst liquid including the catalyst 22a is discharged from the discharge nozzle 32 of the nozzle head 104 onto the substrate 2, so that the catalyst 22a is adsorbed onto the adhesion layer 21 of the substrate 2, and, thus, the catalyst layer 22 may be formed. Further, the remaining catalyst liquid on the substrate 2 may be removed by discharging the cleaning liquid from the nozzle 92 of the nozzle head 104.

Hereinafter, the catalyst liquid supplied to the substrate 2 and the catalyst 22a included in the catalyst liquid will be described. Firstly, the catalyst 22a will be described.

As the catalyst 22a adsorbed onto the adhesion layer 21 of the substrate 2, a catalyst having the catalysis that promotes a plating reaction may be appropriately used. By way of example, a catalyst formed of a nanoparticle may be used. Herein, the nanoparticle refers to a colloidal particle having the catalysis and having an average particle diameter of 20 nm or less, for example, 0.5 nm to 20 nm. Examples of elements constituting the nanoparticle may include palladium, gold, platinum, etc. A palladium nanoparticle may be represented as n-Pd.

Further, as an element constituting the nanoparticle, ruthenium may be used.

A method of measuring an average particle diameter of the nanoparticles is not particularly limited, and various methods may be used. By way of example, in the case of measuring the average particle diameter of the nanoparticles included in the catalyst liquid, a dynamic light scattering method may be used. The dynamic light scattering method refers to a method of measuring the average particle diameter of the nanoparticles by irradiating a laser beam to the nanoparticles dispersed in the catalyst liquid and observing the scattered light. Further, in the case of measuring an average particle diameter of the nanoparticles adsorbed onto the recess 2a in the substrate 2, a predetermined number of nanoparticles, for example, 20 nanoparticles are detected from an image obtained by TEM or SEM, and then, the average particle diameter of these nanoparticles is calculated.

Hereinafter, the catalyst liquid including the catalyst formed of the nanoparticle will be described. The catalyst liquid contains ions of a metal constituting the nanoparticle serving as the catalyst. By way of example, if the nanoparticles are formed of palladium, the catalyst liquid may contain a palladium compound such as palladium chloride as a palladium ion source.

A specific composition of the catalyst liquid is not particularly limited, but desirably, the composition of the catalyst liquid is set such that a viscosity coefficient of the catalyst liquid is 0.01 Pa·s or less. By setting the viscosity coefficient of the catalyst liquid within the above-described range, even if a diameter of the recess 2a in the substrate 2 is small, the catalyst liquid can be sufficiently diffused to a lower portion of the recess 2a in the substrate 2. Thus, the catalyst 22a can be more reliably adsorbed to the lower portion of the recess 2a in the substrate 2.

Desirably, the catalyst 22a in the catalyst liquid is coated with a dispersant. Thus, surface energy at an interface of the catalyst 22a can be low. Therefore, it is assumed that diffusion of the catalyst 22a in the catalyst liquid can be further promoted, and, thus, the catalyst 22a can reach the lower portion of the recess 2a in the substrate 2 in a shorter time. Further, it is assumed that it is possible to suppress multiple catalysts 22a from being agglomerated and thus increased in the particle diameter. As a result, it is possible to promote the diffusion of the catalyst 22a in the catalyst liquid.

A method of preparing the catalyst 22a coated with the dispersant is not particularly limited. By way of example, the catalyst liquid including the catalyst 22a previously coated with the dispersant may be supplied to the catalyst layer forming unit 13. Otherwise, the catalyst layer forming unit 13 may be configured such that a processing of coating the catalyst 22a with the dispersant is performed within the catalyst layer forming unit 13, for example, by the catalyst liquids supply device 30.

To be specific, the dispersant may be desirably polyvinylpyrrolidone (PVP), polyacrylic acid (PAA), polyethyleneimine (PEI), tetramethylammonium (TMA), citric acid, and the like.

Besides, various chemical agents for adjusting characteristics may be added to the catalyst liquid.

The catalyst liquid including the catalyst 22a is not limited to a catalyst liquid including nanoparticles such as n-Pd. An aqueous solution of palladium chloride (PdCl₂) may be used as the catalyst liquid, and Pd ions from palladium chloride (PdCl₂) may be used as the catalyst 22a.

As such, after the catalyst layer 22 is formed on the adhesion layer 21 of the substrate 2 in the catalyst layer forming unit 13, the substrate 2 is transferred to the heating unit 15 by the substrate transfer arm 11 to be heated by the heating unit 15. As a result, the catalyst layer 22 is baked (baking processing). In this case, in the airtightly sealed casing 15a of the heating unit 15, the substrate 2 on the hot plate 15A is heated for 10 minutes to 30 minutes at a temperature in the range of, for example, 150° C. to 250° C. in a N₂ gas atmosphere and the catalyst layer 22 is heated to be baked. Further, this baking processing of the catalyst layer 22 may not be necessarily performed.

After the catalyst layer 22 is formed, the substrate 2 on which the catalyst layer 22 is baked is transferred into the catalyst fixing layer forming unit 20 by the substrate transfer arm 11. Then, a material for forming a catalyst fixing layer is coated on the catalyst layer 22 of the substrate 2 from, for example, the spray-type coating device in the catalyst fixing layer forming unit 20, so that the catalyst fixing layer 27 is formed on the catalyst layer 22 (see FIG. 3C).

Examples of the material for forming the catalyst fixing layer may include organic insulating materials (SOG, Low-k), or inorganic insulating materials (Si—O—C).

The catalyst fixing layer 27 formed on the catalyst layer 22 is configured to fix the catalyst layer 22 including the catalyst 22a on the adhesion layer 21 of the substrate 2. As a result, the catalyst fixing layer 27 can suppress the catalyst 22a adsorbed onto the adhesion layer 21 from being peeled off.

In this case, an average thickness of the catalyst fixing layer 27 is 0.2 to 1.0 times the average particle diameter of the catalyst 22a.

If the average thickness of the catalyst fixing layer 27 is smaller than 0.2 times the average particle diameter of the catalyst 22a, it is difficult for the catalyst fixing layer 27 to firmly fix the catalyst layer 22 on the substrate 2. If the average thickness of the catalyst fixing layer 27 is greater than 1.0 times the average particle diameter of the catalyst 22a, the catalyst 22a cannot be exposed to an upper side of the catalyst fixing layer 27 and thus cannot serve as a catalyst during a plating processing in a post-processing.

For this reason, the average thickness of the catalyst fixing layer 27 is set to be in the above-described range.

As such, after the catalyst fixing layer 27 is formed on the catalyst layer 22 of the substrate 2 in the catalyst fixing layer forming unit 20, the substrate 2 is transferred into the heating unit 15 by the substrate transfer arm 11, and the substrate 2 on the hot plate 15A is heated in a N₂ gas atmosphere within the airtightly sealed casing 15a of the heating unit 15 and the catalyst fixing layer 27 is baked (baking processing). In this case, the substrate 2 is heated in the heating unit 15 for 10 minutes to 30 minutes at a temperature in the range of, for example, 150° C. to 250° C., so that the catalyst fixing layer 27 is heated to be baked.

Further, if the material for forming the catalyst fixing layer 27 includes a solvent, it is desirable to sufficiently heat the material within the heating unit 15 and completely remove the solvent in the catalyst fixing layer 27.

Thus, a catalyst layer 22A including the catalyst layer 22 and the catalyst fixing layer 27 for fixing the catalyst layer 22 is obtained.

As described above, according to the present exemplary embodiment, the catalyst layer 22 is formed by adsorbing the catalyst 22a on the adhesion layer 21 including the SAM layer 21a on the TEOS layer 2A of the substrate 2, and the catalyst fixing layer 27 is formed on the catalyst layer 22. As a result, it is possible to reliably fix the catalyst layer 22 on the substrate 2 with the catalyst fixing layer 27 (see FIG. 4A).

Meanwhile, in a case where the catalyst fixing layer 27 is not formed on the catalyst layer 22 as shown in a comparative example illustrated in FIG. 5A, a delamination phenomenon may occur at an interface between the adhesion layer 21 and the catalyst layer 22 when forming the plating layer 23 on the catalyst layer 22 as described later.

In this regard, according to the present exemplary embodiment, since the catalyst layer 22 is fixed on the substrate 2 with the catalyst fixing layer 27, the delamination phenomenon does not occur at the interface between the adhesion layer 21 and the catalyst layer 22.

Further, according to the present exemplary embodiment, the catalyst layer 22 is formed by adsorbing the catalyst 22a on the adhesion layer 21 including the SAM layer 21a and the TPT layer 21b on the TEOS layer 2A of the substrate 2, and the catalyst fixing layer 27 is formed on the catalyst layer 22. As a result, it is possible to reliably fix the catalyst layer 22 on the substrate 2 with the catalyst fixing layer 27 (see FIG. 4B).

Meanwhile, in a case where the catalyst fixing layer 27 is not formed on the catalyst layer 22 as shown in a comparative example illustrated in FIG. 5B, a delamination phenomenon may occur at the interface between the adhesion layer 21 and the catalyst layer 22 when forming the plating layer 23 is formed on the catalyst layer 22 as described later.

In this regard, according to the present exemplary embodiment, since the catalyst layer 22 is fixed on the substrate 2 with the catalyst fixing layer 27, the delamination phenomenon does not occur at the interface between the adhesion layer 21 and the catalyst layer 22.

As such, after the catalyst fixing layer 27 is formed on the substrate 2 in the catalyst fixing layer forming unit 20, the substrate 2 is transferred into the plating layer forming unit 14 by the substrate transfer arm 11.

Subsequently, in the plating layer forming unit 14, the plating layer 23 serving as a Cu diffusion barrier film (barrier film) is formed on the catalyst layer 22 of the substrate 2 (FIG. 3D).

In this case, the plating layer forming unit 14 is configured as the liquid processing apparatus as illustrated in FIG. 8 and FIG. 9. The plating layer 23 can be formed by performing an electroless plating processing on the catalyst layer 22 of the substrate 2.

When forming the plating layer 23 in the plating layer forming unit 14, a plating liquid containing, for example, Co—W—B may be used, and a temperature of the plating liquid is maintained at 40° C. to 75° C. (desirably, 65° C.).

By supplying the plating liquid containing the Co—W—B onto the substrate 2, the plating layer 23 containing the Co—W—B is formed on the catalyst layer 22 of the substrate 2 through the electroless plating processing.

Thereafter, the substrate 2, in which the plating layer 23 is formed on the catalyst layer 22, is transferred from the plating layer forming unit 14 into the airtightly sealed casing 15a of the heating unit 15 by the substrate transfer arm 11. Within the airtightly sealed casing 15a of the heating unit 15, the substrate 2 on the hot plate 15A is heated under a N₂ gas atmosphere. Accordingly, the plating layer 23 of the substrate 2 is baked (baking processing).

When baking the plating layer 23 in the heating unit 15, a baking temperature may be set to be in the range from, e.g., 150° C. to 200° C., and a baking time is set to be in the range from, e.g., 10 minutes to 30 minutes.

By baking the plating layer 23 on the substrate 2 as described above, moisture within the plating layer 23 can be removed outside, and, at the same time, the bond between metals within the plating layer 23 can be strengthened.

The plating layer 23 formed as such serves as the Cu diffusion barrier film (barrier film). Then, the substrate 2 on which the plating layer 23 serving as the barrier film is formed is transferred into the electroless Cu plating layer forming unit 16 by the substrate transfer arm 11.

Subsequently, in the electroless Cu plating layer forming unit 16, an electroless Cu plating layer 24 serving as a seed film for forming an electrolytic Cu plating layer 25 is formed on the plating layer 23 of the substrate 2 (FIG. 3E).

Here, the electroless Cu plating layer forming unit 16 is configured as the liquid processing apparatus as illustrated in FIG. 8 and FIG. 9. By performing the electroless plating processing on the plating layer 23 of the substrate 2, the electroless Cu plating layer 24 can be formed.

The electroless Cu plating layer 24 formed in the electroless Cu plating layer forming unit 16 serves as the seed film for forming the electrolytic Cu plating layer 25. A plating liquid used in the electroless Cu plating layer forming unit 16 may contain a copper salt as a source of copper ions, such as copper sulfate, copper nitrate, copper chloride, copper bromide, copper oxide, copper hydroxide, copper pyrophosphate, or the like. The plating liquid may further contain a reducing agent and a complexing agent for the copper ions. Further, the plating liquid may further contain various kinds of additives for improving stability or speed of the plating reaction.

The substrate 2 on which the electroless Cu plating layer 24 is formed as described above is then sent to the electrolytic Cu plating layer forming unit 17 by the substrate transfer arm 11. Here, the substrate 2 on which the electroless Cu plating layer 24 is formed may be sent to the electrolytic Cu plating layer forming unit 17 after transferred into the heating unit 15 to be baked therein. Subsequently, an electrolytic Cu plating processing is performed on the substrate 2 within the electrolytic Cu plating layer forming unit 17, so that the electrolytic Cu plating layer 25 is buried within the recess 2a of the substrate 2 while using the electroless Cu plating layer 24 as the seed film (FIG. 3F).

Thereafter, the substrate 2 is carried out from the plating system 10, and a rear surface side of the substrate 2 (opposite side to the side where the recess 2a is formed) is polished chemically and mechanically (FIG. 3G).

In the above-described exemplary embodiment, the electrolytic Cu plating layer is formed through the electrolytic Cu plating processing. However, the exemplary embodiment may not be limited thereto, and it may be possible to form the Cu plating layer through the electroless Cu plating processing instead of the electrolytic Cu plating processing.

Additionally, in the above-described exemplary embodiment, when heating the substrate 2, the substrate 2 is heated on the hot plate 15A under the inert-gas atmosphere of N₂ gas within the airtightly sealed casing 15a of the heating unit 15. However, the exemplary embodiment may not be limited thereto, and the substrate 2 may be heated on the hot plate 15A after evacuating the inside of the airtightly sealed casing 15a to a vacuum level, in order to lower the temperature or shorten the processing time.

Furthermore, in the above-described exemplary embodiment, the catalyst layer forming unit 13 and the heating unit 15 are configured as individual apparatuses. However, the exemplary embodiment may not be limited thereto. By way of example, by providing a heating source such as a lamp irradiator 200 (UV light or the like) above the substrate 2 or a hot plate (not shown) covering the substrate 2 in the catalyst layer forming unit 13 shown in FIG. 8, it may be possible to bake the catalyst layer within the catalyst layer forming unit 13. Further, there has been described an example where the plating layer 23 serving as the Cu diffusion barrier film is formed on the catalyst layer 22 of the substrate 2. However, the catalyst layer 22 may be formed on the plating layer 23 serving as the barrier film and the electroless Cu plating layer 24 serving as the seed film may be formed on the catalyst layer 22.

### EXAMPLE

### Experimental Example 1

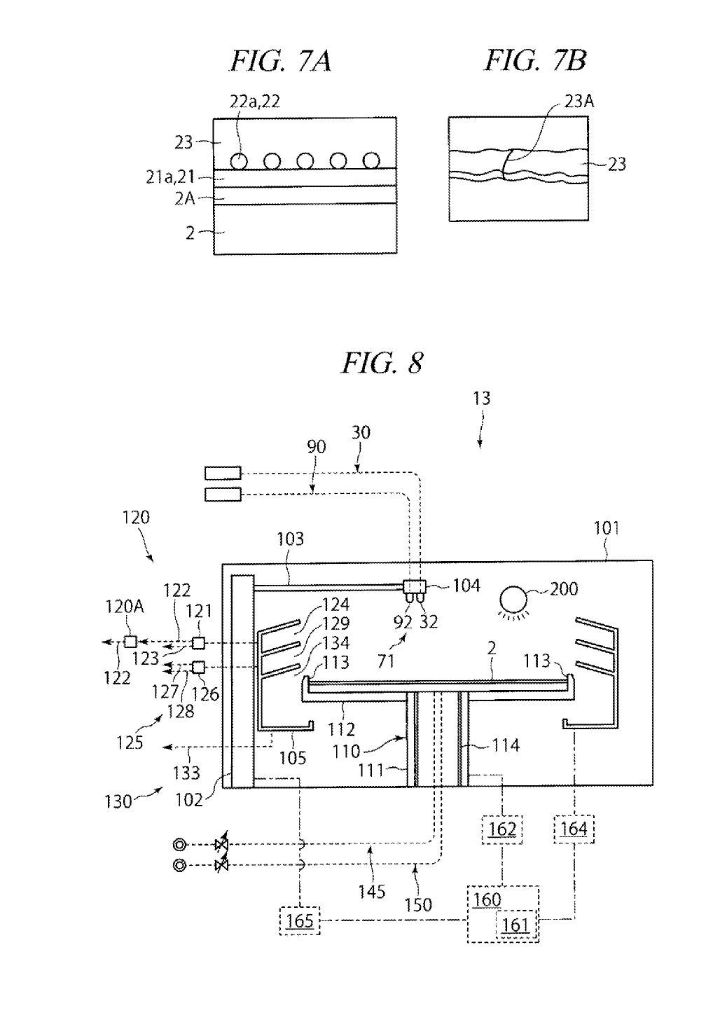

Hereinafter, a specific example will be described with reference to FIGS. 6A and 6B and FIGS. 7A and 7B. As illustrated in FIGS. 6A and 6B, the adhesion layer 21 including the SAM layer 21a is formed on the TEOS layer 2A of the substrate 2 and the catalyst layer 22 is formed by adsorbing the catalyst 22a formed of n-Pd on the adhesion layer 21. Then, the catalyst fixing layer 27 is formed on the catalyst layer 22 to fix the catalyst layer 22 onto the adhesion layer 21 of the substrate 2, and the plating layer 23 of a CoWB film is formed by using the catalyst 22a of the catalyst layer 22.

Then, as a result of conducting a tape test in which a tape is attached to the plating layer 23 and then detached therefrom, a peeled-off portion is not observed from the plating layer 23.

### Comparative Example

In a comparative example, as illustrated in FIGS. 7A and 7B, the adhesion layer 21 including the SAM layer 21a is formed on the TEOS layer 2A of the substrate 2 and the catalyst layer 22 is formed by adsorbing the catalyst 22a formed of n-Pd on the adhesion layer 21. Then, the catalyst fixing layer 27 is not formed on the catalyst layer 22, but the plating layer 23 of a CoWB film is formed by using the catalyst 22a of the catalyst layer 22.

Then, as a result of conducting the tape test in which the tape is attached to the plating layer 23 and then detached therefrom, a peeled-off portion 23A is observed from the plating layer 23.

As mentioned above, a delamination occurs at the interface between the adhesion layer 21 and the catalyst layer 22, and the peeled-off portion 23A of the plating layer 23 is caused by the delamination at an interface between the adhesion layer 21 and the catalyst layer 22.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A pre-treatment method of plating, comprising:
preparing a substrate;
forming a catalyst layer by adsorbing a catalyst on the substrate; and
forming a catalyst fixing layer, which is configured to fix the catalyst to the substrate, on the catalyst layer.

2. The pre-treatment method of claim 1,
wherein an average thickness of the catalyst fixing layer is set to be in a range in which at least an upper portion of the catalyst is exposed.

3. The pre-treatment method of claim 1,
wherein an adhesion layer is previously formed on the substrate to be adjacent to the catalyst layer before the forming of the catalyst layer.

4. The pre-treatment method of claim 3,
wherein the adhesion layer is configured as an adhesion layer formed of a silane coupling agent or an adhesion layer formed of a titanate agent, or configured as a stacked body including the adhesion layer formed of the silane coupling agent and the adhesion layer formed of the titanate agent.

5. The pre-treatment method of claim 1,
wherein a barrier layer is previously formed on the substrate to be adjacent to the catalyst layer before the forming of the catalyst layer.

6. The pre-treatment method of claim 1, further comprising:
baking the catalyst fixing layer by heating the substrate after the forming of the catalyst fixing layer.

7. The pre-treatment method of claim 6, further comprising:
baking the catalyst layer by heating the substrate before the forming of the catalyst fixing layer.

8. A plating system comprising:
a catalyst layer forming unit configured to form a catalyst layer by adsorbing a catalyst on a substrate;
a catalyst fixing layer forming unit configured to form a catalyst fixing layer, which is configured to fix the catalyst to the substrate, on the catalyst layer; and
a substrate transfer unit configured to transfer the substrate between the catalyst layer forming unit and the catalyst fixing layer forming unit.

9. The plating system of claim 8,
wherein the catalyst fixing layer forming unit is configured to set an average thickness of the catalyst fixing layer to be in a range in which at least an upper portion of the catalyst is exposed.

10. The plating system of claim 8,
wherein an adhesion layer forming unit configured to form an adhesion layer on the substrate is provided.

11. The plating system of claim 8,
wherein a barrier layer forming unit configured to form a barrier layer on the substrate is provided.

12. The plating system of claim 8, further comprising:
a first heating unit configured to bake the catalyst fixing layer by heating the substrate.

13. The plating system of claim 8, further comprising:
a second heating unit configured to bake the catalyst layer by heating the substrate.

14. A computer-readable recording medium having stored thereon computer-executable instructions that, in response to execution, cause a plating system to perform a pre-treatment method of plating,
wherein the pre-treatment method includes:
preparing a substrate;
forming a catalyst layer by adsorbing a catalyst on the substrate; and
forming a catalyst fixing layer, which is configured to fix the catalyst to the substrate, on the catalyst layer.
